(19) United States
(12) Patent Application Publication
(10) Pub. No.: US 2019/0051500 A1
(43) Pub. Date: Feb. 14, 2019

(54) PLASMA PROCESSING METHOD AND PLASMA PROCESSING APPARATUS

(71) Applicant: Tokyo Electron Limited, Tokyo (JP)

(72) Inventors: Takanori Eto, Kurokawa-gun (JP); Masayuki Sawataishi, Kurokawa-gun (JP)

(21) Appl. No.: 16/100,446

(22) Filed: Aug. 10, 2018

(30) Foreign Application Priority Data
Aug. 14, 2017 (JP) 2017-156313

(51) Int. Cl. H01J 37/32; H01L 21/311

(52) U.S. Cl. CPC H01J 37/32449; H01J 37/32091; H01L 21/31144; H01L 21/31116; H01J 37/32532

(57) ABSTRACT

Both a conductive layer selectivity and a mask selectivity can be achieved. A plasma processing method includes supplying a processing gas containing at least a fluorocarbon-based gas or a hydrofluorocarbon-based gas and CO into a processing vessel in which a multilayered film having at least an oxide layer, a conductive layer provided under the oxide layer and a mask layer provided on a top surface of the oxide layer is disposed; and etching the multilayered film by generating plasma within the processing vessel into which the processing gas is supplied.

### CROSS-REFERENCE TO RELATED APPLICATION

This application claims the benefit of Japanese Patent Application No. 2017-156313 filed on Aug. 14, 2017, the entire disclosures of which are incorporated herein by reference.

### TECHNICAL FIELD

The various aspects and embodiments described herein pertain generally to a plasma processing method and a plasma processing apparatus.

### BACKGROUND

Conventionally, there is known a plasma processing method of etching a multilayered film having an oxide layer, a conductive layer such as a metal layer provided under the oxide layer and a mask layer provided on a top surface of the oxide layer (see, for example, Patent Document 1). To meet a requirement for a next-generation device, a number of layers stacked in this multilayered film is getting increased. By way of example, the number of layers stacked in a NAND type flash memory having a multilayered film of a 3D structure is getting increased. Along with this trend, an aspect ratio of a hole to be etched is also getting increased.

Patent Document 1: Japanese Patent Laid-open Publication No. 2014-090022

### SUMMARY

In plasma etching for a hole or a groove having a high aspect ratio, as the etching progresses, there occurs depth loading, that is, a phenomenon that the etching does not progress at a bottom of the hole or the groove, resulting a great increase of an etching time. For this reason, both conductive layer selectivity and mask selectivity are required to be satisfied in the plasma etching.

To improve metal selectivity, it may be desirable to supply sufficient polymer onto the bottom of the hole to form a protective film by highly dissociating a fluorocarbon-based gas as an etching gas with plasma. Since, however, dissociation of fluorine radicals serving as etchants for the mask from the fluorocarbon-based gas is accelerated at the same time, it may be regarded that the conductive layer selectivity and the mask selectivity are in a trade-off relationship.

In one exemplary embodiment, a plasma processing method includes supplying a processing gas containing at least a fluorocarbon-based gas or a hydrofluorocarbon-based gas and CO into a processing vessel in which a multilayered film having at least an oxide layer, a conductive layer provided under the oxide layer and a mask layer provided on a top surface of the oxide layer is disposed; and etching the multilayered film by generating plasma within the processing vessel into which the processing gas is supplied.

According to the exemplary embodiment, it is possible to achieve both the conductive layer selectivity and the mask selectivity.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a diagram illustrating a plasma processing apparatus according to an exemplary embodiment;

FIG. 2 is a schematic diagram of a NAND type flash memory;

FIG. 3 is a schematic cross sectional view showing portions where metal contacts are formed;

FIG. 4 is a diagram illustrating an example of a multilayered film;

FIG. 5 is a diagram schematically illustrating hole shapes;

FIG. 6 is a table showing an example of measurement results of an ACL selectivity and a tungsten selectivity;

FIG. 7 is a diagram showing an example of a variation of the ACL selectivity;

FIG. 8 is a diagram showing an example of a variation of the tungsten selectivity;

FIG. 9 is a diagram schematically illustrating hole shapes; and

FIG. 10 is a diagram showing an example of the variations of the tungsten selectivity and the ACL selectivity.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, a plasma processing method and a plasma processing apparatus according to exemplary embodiments will be explained in detail with reference to the accompanying drawings. In the exemplary embodiments, same or corresponding parts will be assigned same reference numerals. Further, the exemplary embodiments described herein are not meant to be anyway limiting. The various exemplary embodiments can be appropriately combined as long as the contents of processings are not contradictory.

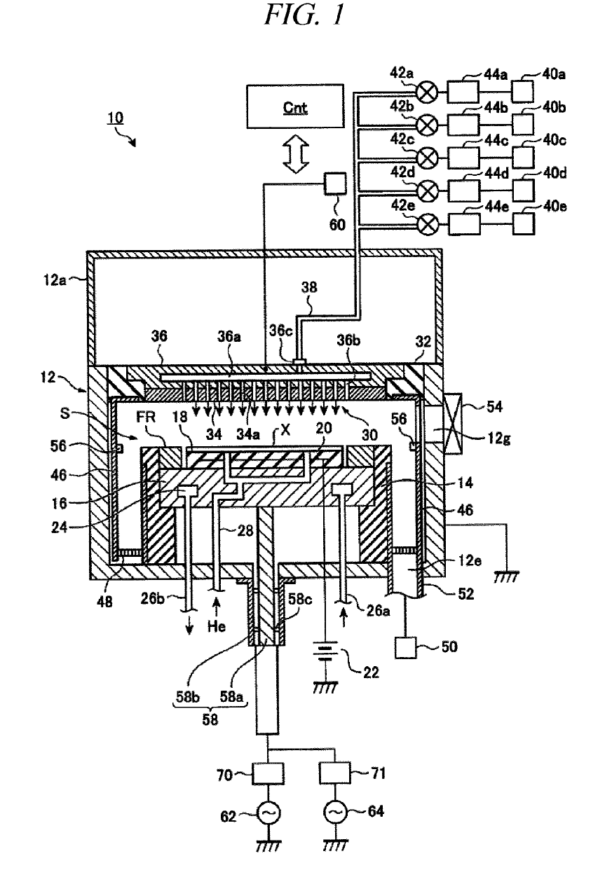

FIG. 1 is a diagram illustrating a plasma processing apparatus according to an exemplary embodiment. A plasma processing apparatus 10 shown in FIG. 1 is configured as a capacitively coupled parallel plate type plasma etching apparatus, and is equipped with a substantially cylindrical processing vessel 12. The processing vessel 12 is made of, by way of non-limiting example, aluminum having an anodically oxidized surface. The processing vessel 12 is frame-grounded.

A cylindrical supporting member 14 made of an insulating material is placed on a bottom portion of the processing vessel 12. The supporting member 14 is configured to support a base 16 which is made of a metal such as, but not limited to, aluminum. This base 16 is provided within the processing vessel 12 and, in the present exemplary embodiment, the base 16 constitutes a lower electrode.

An electrostatic chuck 18 is provided on a top surface of the base 16. The electrostatic chuck 18 and the base 16 constitute a mounting table according to the exemplary embodiment. The electrostatic chuck 18 has a structure in which an electrode 20 made of a conductive film is embedded between a pair of insulating layers or insulating sheets. The electrode 20 is electrically connected with a DC power supply 22. The electrostatic chuck 18 is configured to attract and hold a processing target object (workpiece) X by an electrostatic force such as Coulomb force generated by a DC voltage applied from the DC power supply 22.

A focus ring FR is disposed on the top surface of the base 16 to surround the electrostatic chuck 18. The focus ring FR is configured to improve etching uniformity. The focus ring FR is made of a material which is appropriately selected based on a material of an etching target layer. By way of non-limiting example, the focus ring FR may be made of silicon or quartz.

A coolant path 24 is provided within the base 16. A coolant of a set temperature, for example, cooling water is supplied into the coolant path 24 from an external chiller unit via pipelines 26a and 26b to be circulated therein. By controlling a temperature of the coolant circulated in this way, a temperature of the processing target object X placed on the electrostatic chuck 18 is also controlled.

Further, the plasma processing apparatus 10 is equipped with a gas supply line 28. Through the gas supply line 28, a heat transfer gas, for example, a He gas from a heat transfer gas supply mechanism is supplied into a gap between a top surface of the electrostatic chuck 18 and a rear surface of the processing target object X.

Further, an upper electrode 30 is provided within the processing vessel 12. The upper electrode 30 is disposed above the base 16, facing the base 16. The base 16 and the upper electrode 30 are arranged substantially in parallel to each other. A space between the upper electrode 30 and the base 16 functioning as the lower electrode serves as a processing space S in which a plasma etching is performed on the processing target object X.

The upper electrode 30 is supported at an upper portion of the processing vessel 12 with an insulating shield member 32 therebetween. The upper electrode 30 may include an electrode plate 34 and an electrode supporting body 36. The electrode plate 34 faces the processing space S, and is provided with a multiple number of gas discharge holes 34a. The electrode plate 34 may be made of a low-resistance conductor or semiconductor having low Joule heat.

The electrode supporting body 36 is configured to support the electrode plate 34 in a detachable manner, and is made of a conductive material such as, but not limited to, aluminum. The electrode supporting body 36 may have a water-cooling structure. A gas diffusion space 36a is formed within the electrode supporting body 36. A multiple number of gas through holes 36b are extended downwards from the gas diffusion space 36a, and these gas through holes 36b respectively communicate with the gas discharge holes 34a. Further, the electrode supporting body 36 is provided with a gas inlet opening 36c through which a processing gas is introduced into the gas diffusion space 36a, and a gas supply line 38 is connected to this gas inlet opening 36c.

The gas supply line 38 is connected to gas sources 40a to 40e via valves 42a to 42e and mass flow controllers (MFC) 44a to 44e, respectively. Further, a FCS may be provided instead of the MFC. The gas source 40a is a source of a processing gas containing a fluorocarbon-based gas or a hydrofluorocarbon-based gas. The fluorocarbon-based gas may be a CₓF_{y} gas such as, but not limited to, C₄F₆, C₃F₆, C₄F₈, C_{S}F₈ or C₆F₆. The hydrofluorocarbon-based gas may be a CHₓF_{y}-based gas such as, but not limited to, CH₂F₂, CHF₃ or CH₃F. The gas source 40b is a source of a processing gas containing a rare gas such as, but not limited to, an Ar gas. The gas source 40c is a source of a processing gas containing, for example, oxygen. The gas source 40d is a source of a processing gas containing, for example, nitrogen. The gas source 40e is a source of a processing gas containing, for example, carbon monoxide (CO). The processing gas from these gas sources 40a to 40e reaches the gas diffusion space 36a through the gas supply line 38 to be discharged into the processing space S through the gas through holes 36b and the gas discharge holes 34a. The gas sources 40a to 40e, the valves 42a to 42e, the MFCs 44a to 44e, the gas supply line 38, and the upper electrode 30 provided with the gas diffusion space 36a, the gas through holes 36b and the gas discharge holes 34a constitute a supply unit in the exemplary embodiment.

Further, the plasma processing apparatus 10 may be further equipped with a ground conductor 12a. The ground conductor 12a is of a substantially cylindrical shape, and is extended upwards from a sidewall of the processing vessel 12 to be higher than the upper electrode 30.

Further, in the plasma processing apparatus 10, a deposition shield 46 is provided along an inner wall of the processing vessel 12 in a detachable manner. The deposition shield 46 is also provided on an outer side surface of the supporting member 14. The deposition shield 46 is configured to suppress an etching byproduct (deposit) from adhering to the processing vessel 12, and is formed by coating an aluminum member with ceramic such as Y₂O₃.

At a bottom side of the processing vessel 12, a gas exhaust plate 48 is provided between the supporting member 14 and the inner wall of the processing vessel 12. The gas exhaust plate 48 may be made of, by way of example, an aluminum member coated with ceramic such as Y₂O₃. A gas exhaust opening 12e is formed at the processing vessel 12 under the gas exhaust plate 48. The gas exhaust opening 12e is connected with a gas exhaust device 50 via a gas exhaust line 52. The gas exhaust device 50 includes a vacuum pump such as a turbo molecular pump, and is capable of decompressing the inside of the processing vessel 12 to a required vacuum level. The gas exhaust device 50 maintains the inside of the processing vessel 12 at a vacuum level equal to or less than, e.g., 0.1 mTorr (0.01 Pa). Further, a carry-in/out opening 12g for the processing target object X is provided at the sidewall of the processing vessel 12, and this carry-in/out opening 12g is opened/closed by a gate valve 54.

Further, a conductive member (GND block) 56 is provided at the inner wall of the processing vessel 12. The conductive member 56 is mounted to the inner wall of the processing vessel 12 to be substantially on a level with the processing target object X in a height direction. This conductive member 56 is DC-connected to the ground and configured to suppress an abnormal discharge. Further, the location of the conductive member 56 is not limited to the example shown in FIG. 1 as long as it is provided in a plasma generation region. By way of example, the conductive member 56 may be provided on the side of the base 16, for example, around the base 16, or may be provided in the vicinity of the upper electrode 30, for example, in a ring shape at an outside of the upper electrode 30.

In the exemplary embodiment, the plasma processing apparatus 10 is further equipped with a power feed rod 58 configured to supply a high frequency power to the base 16 constituting the lower electrode. The power feed rod 58 constitutes a power feed line according to the exemplary embodiment. The power feed rod 58 has a coaxial double-pipe structure, and includes a rod-shaped conductive member 58a and a cylindrical conductive member 58b. The rod-shaped conductive member 58a is extended in a substantially vertical direction from an outside of the processing vessel 12 to an inside of the processing vessel 12 through the bottom portion of the processing vessel 12. An upper end of the rod-shaped conductive member 58a is connected to the base 16. Further, the cylindrical conductive member 58b is provided coaxially with the rod-shaped conductive member 58a to surround the rod-shaped conductive member 58a, and is supported at the bottom portion of the processing vessel 12. Two sheets of insulating members 58c having substantially annular shape are provided between the rod-shaped conductive member 58a and the cylindrical conductive member 58b, so that the rod-shaped conductive member 58a and the cylindrical conductive member 58b are electrically insulated from each other.

Further, in the exemplary embodiment, the plasma processing apparatus 10 may be further equipped with matching devices 70 and 71. The matching devices 70 and 71 are connected to lower ends of the rod-shaped conductive member 58a and the cylindrical conductive member 58b. The matching device 70 and the matching device 71 are connected to a first high frequency power supply 62 and a second high frequency power supply 64, respectively. The first high frequency power supply 62 is configured to generate a first high frequency (RF (radio frequency)) power for plasma generation having a frequency ranging from 27 MHz to 100 MHz, for example, 40 MHz. Further, the first high frequency power is of 1000 W to 3000 W, for example. The second high frequency power supply 64 is configured to generate a second high frequency power for ion attraction to the processing target object X by applying a high frequency bias to the base 16. A frequency of the second high frequency power is in a range from 400 kHz to 13.56 MHz, for example, 3 MHz. Further, the second high frequency power is of 3000 W to 8000 W, for example. A DC power supply 60 is connected to the upper electrode 30 via a non-illustrated low pass filter. The DC power supply 60 outputs a negative DC voltage to the upper electrode 30. With the above-described configuration, the two different high frequency powers can be supplied to the base 16 serving as the lower electrode, and the DC voltage can be applied to the upper electrode 30. The upper electrode 30, the base 16, the first high frequency power supply 62, the second high frequency power supply 64, the DC power supply 60, and so forth constitute a plasma generation unit according to the exemplary embodiment.

Further, in the exemplary embodiment, the plasma processing apparatus 10 may further include a control unit Cnt. The control unit Cnt is implemented by a computer including a processor, a storage unit, an input device, a display device, and so forth. The control unit Cnt is configured to control individual components of the plasma processing apparatus 10 such as a power supply system, a gas supply system, a driving system, and so forth. In the control unit Cnt, an operator can input commands through the input device to manage the plasma processing apparatus 10. Further, an operational status of the plasma processing apparatus 10 can be visually displayed on the display device. Further, the storage unit of the control unit Cnt stores therein a control program for controlling various processings performed in the plasma processing apparatus 10 by the processor, or a program for allowing each component of the plasma processing apparatus 10 to perform a processing according to processing conditions, i.e., a processing recipe.

To perform the etching in the plasma processing apparatus 10, the processing target object X is placed on the electrostatic chuck 18. The processing target object X may have an etching target layer and a resist mask provided on the etching target layer. While evacuating the processing vessel 12 by the gas exhaust device 50, the processing gas is supplied from the gas sources 40a to 40e into the processing vessel 12 at a preset flow rate, and an internal pressure of the processing vessel 12 is set to be in a range from, by way of example, but not limitation, 5 mTorr to 500 mTorr (0.67 Pa to 66.5 Pa).

Thereafter, the first high frequency power supply 62 supplies the first high frequency power to the base 16 serving as the lower electrode. Further, the second high frequency power supply 64 supplies the second high frequency power to the base 16. Furthermore, the DC power supply 60 supplies a first DC voltage to the upper electrode 30. As a result, a high frequency electric field is formed between the upper electrode 30 and the base 16 serving as the lower electrode, and the processing gas supplied into the processing space S is excited into plasma. The etching target layer of the processing target object X is etched by positive ions or radicals generated by this plasma.

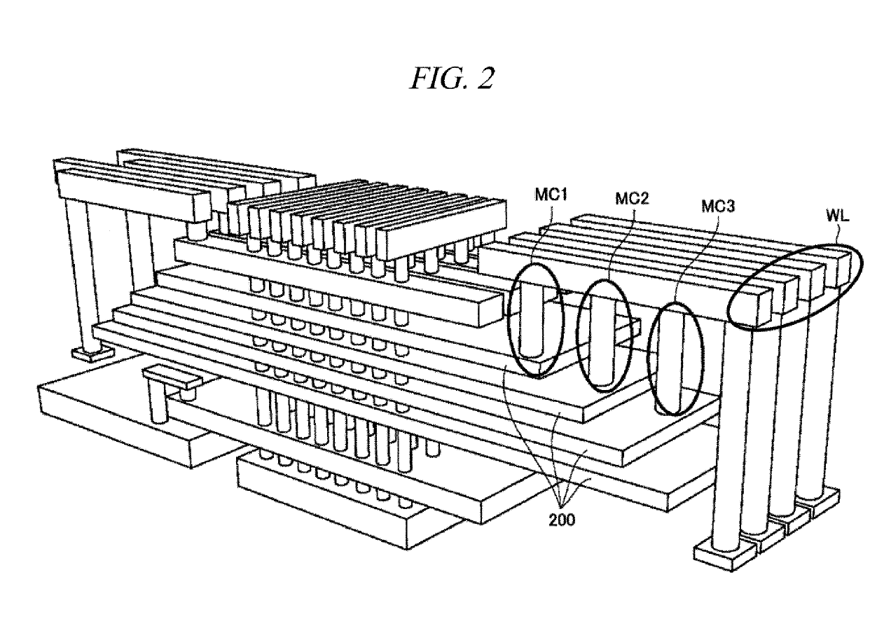

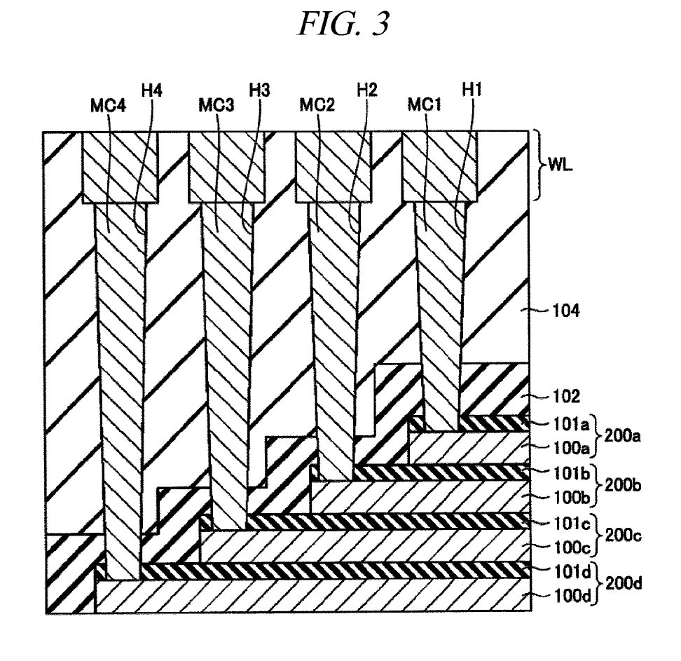

Now, an example of the processing target object X etched by the above-described plasma processing apparatus 10 will be explained. The processing target object X is used to form, for example, a NAND type flash memory having a multilayered film of a three dimensional structure. FIG. 2 is a schematic diagram illustrating the NAND type flash memory. As shown in FIG. 2, multilayered wiring layers 200 have metal contacts MC1 to MC4, respectively, for supplying electric potentials of word lines WL. To form these metal contacts, end portions of the multilayered wiring layers 200 are formed to have a step shape. FIG. 3 is a schematic cross sectional view illustrating portions where the metal contacts MC1 to MC4 are formed. In FIG. 3, a schematic cross section of the portions where the metal contacts MC1 to MC4 are formed is illustrated. As depicted in FIG. 3, the multilayered wiring layer 200a (200b, 200c, 200d) has, for example, an insulating layer 101a (101b, 101c, 101d) and a conductive layer 100a (100b, 100c, 100d). The conductive layers 100a to 100d are made of a metal such as, but not limited to, tungsten (W), or may be titanium (Ti), aluminum (Al) or copper (Cu), or may be a silicon containing layer having conductivity such as polycrystalline silicon (Poly-Si) or non-crystalline silicon. The multilayered wiring layer 200d located at the bottommost portion has the longest length, and the multilayered wiring layer 200a located at the topmost portion has the shortest length. That is, the lengths of the multilayered wiring layers 200a to 200d are set to be gradually shortened as it goes from the bottommost portion to the multilayered wiring layer 200a as the topmost portion. An insulating layer 102 and an interlayer insulating layer 104 are formed on the respective multilayered wiring layers 200a to 200d. The insulating layers 101a to 101d, the insulating layer 102 and the interlayer insulating layer 104 are made of, by way of non-limiting example, a silicon-containing insulating film such as a silicon oxide film SiO₂ or a silicon nitride film (SiN). The metal contacts MC1 to MC4 are formed by depositing a conductive material such as a metal within holes H1 to H4 formed in the interlayer insulating layer 104, the insulating layer 102 and the insulating layers 101a to 101d. The holes H1 to H4 are formed at the same time by etching the insulating layers 101a to 101d, the insulating layer 102 and the interlayer insulating layer 104 with the conductive layers 100a to 100d as underlayers (etching stop layers). The holes H1 to H4 have all different depths. To form these metal contacts MC1 to MC4 having the different depths, holes having different depths need to be formed at one time by plasma etching.

In the NAND type flash memory having the multilayered film of the three dimensional structure, a number of layers stacked is getting increased. Along with such an increase, an aspect ratio of a hole to be etched is also getting increased. In the plasma etching for a hole or a groove having such a high aspect ratio, the depth loading may occur as the etching progresses, so that an etching time will be greatly increased. For this reason, in the plasma etching, both a conductive layer selectivity and a mask selectivity are required to be satisfied.

The present inventors have found out that both the conductive layer selectivity and the mask selectivity can be achieved by appropriately adding a carbon monoxide (CO) gas to the processing gas used in the etching. It may be deemed to be because CO forms COF by being bonded with a F radical to scavenge the F radical. That is, the present inventors have found out that the scavenging of the fluorine radical generated by the plasma is effective to obtain both the conductive layer selectivity and the mask selectivity. Particularly, the carbon monoxide (CO) gas allows the fluorine radical to be scavenged as it is exhausted by being selectively bonded with the fluorine radical.

In the plasma processing apparatus 10 according to the exemplary embodiment, a processing gas containing at least a fluorocarbon-based gas or a hydrofluorocarbon-based gas and CO is used as a processing gas for etching. A rare gas may be further added to the processing gas. By way of example, the plasma processing apparatus 10 according to the exemplary embodiment performs an etching processing of forming a hole in the processing target object X by supplying, from the gas sources 40a to 40e, the fluorocarbon-based gas or the hydrofluorocarbon-based gas, the rare gas, the oxygen, the nitrogen and the CO at preset flow rates as the processing gas for the etching into the processing vessel 12. Accordingly, in the plasma processing apparatus 10, the conductive layer selectivity and the mask selectivity can be both achieved. It may be desirable to use the fluorocarbon-based gas as the processing gas and to use a C₄F₆ gas as the fluorocarbon-based gas. Further, since the CO scavenges the F radical, the same effect of improving the conductive layer selectivity and the mask selectivity may be obtained even when another fluorocarbon-based gas or hydrofluorocarbon-based gas other than the C₄F₆ gas is used as the processing gas.

It is desirable to set the flow rate of the CO to be equal to or higher than 55% of a total flow rate of the rare gas and the CO. Further, it may be more desirable to set the flow rate of the CO to be equal to or higher than 71% of the total flow rate of the rare gas and the CO. Further, it is desirable to set the flow rate of the CO to be equal to or higher than about 55% of a total flow rate of the processing gas. Furthermore, it is desirable to set the flow rate of the CO to be in a range from 9.3 times to 13 times the flow rate of the C₄F₆ gas. By setting the flow rate of the CO in this range, the plasma processing apparatus 10 is capable of implementing etching requiring both the high conductive layer selectivity and the high mask selectivity, for example, the etching for forming the holes for the metal contacts MC1 to MC4 of the NAND type flash memory having the multilayered film of the three dimensional structure.

So far, the various exemplary embodiments have been described. However, the exemplary embodiments are not limiting, and various modifications may be made. By way of example, in the above-described exemplary embodiments, although the two high frequency power supplies are connected to the base 16 serving as the lower electrode, the first high frequency power supply configured to generate the first high frequency power for plasma generation may be connected to either one of the base 16 and the upper electrode 30.

### EXPERIMENTAL EXAMPLES

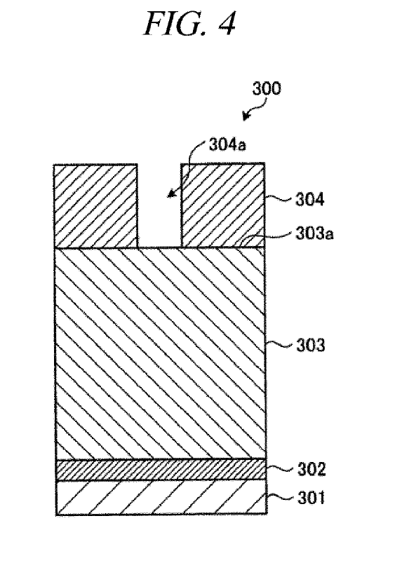

Hereinafter, specific examples where the present inventors have investigated the conductive layer selectivity and the mask selectivity by performing the hole etching on the multilayered film will be explained to describe the aforementioned effects. In the following experimental examples, the hole etching is performed on a multilayered film having a metal layer as the conductive layer, and the mask selectivity and the metal layer selectivity as the conductive layer selectivity are investigated. FIG. 4 is a diagram illustrating an example of the multilayered film. A multilayered film 300 is shown in FIG. 4 by simplifying the processing target object X on which the NAND type flash memory having the multilayered film of the three dimensional structure is formed, for example. By way of example, the hole etching is performed by using the multilayered film 300 as a test sample, and by investigating the metal layer selectivity and a mask selectivity, it is evaluated whether they are suitable for the hole etching performed to form the metal contacts MC1 to MC4 as shown in FIG. 2.

The multilayered film 300 has a substrate 301, a metal layer 302, an insulating layer (oxide layer) 303, and an ACL 304. The substrate 301 is made of, by way of non-limiting example, Si. The metal layer 302 is formed on the substrate 301 and made of, by way of example, but not limitation, tungsten (W). In the NAND type flash memory, for example, the metal layer 302 is a portion serving as the conductive layer 100 (100a to 100d) and the etching stop layer in the multilayered wiring layers 200. A thickness of the metal layer 302 ranges from about 40 nm to 50 nm. The insulating layer 303 is formed on the metal layer 302 and made of, by way of example, SiO₂ or the like. In the NAND type flash memory, for example, the insulating layer 303 is a portion serving as the insulating layer 101 (101a to 101d), the insulating layer 102 and the interlayer insulating layer 104 in the multilayered wiring layers 200. The insulating layer 303 has a thickness of, e.g., 4.7 μm. On top of a top surface 303a of the insulating layer 303 in a stacking direction, the ACL 304 is disposed as the mask layer. The ACL 304 has an opening 304a. The ACL 304 has a thickness of, e.g., 1.6 μm.

Further, in the present exemplary embodiment, conditions for obtaining the high metal layer selectivity and the high mask selectivity are as follows.

Metal layer selectivity>300 Condition (1)

Mask selectivity>7.8 Condition (2)

The condition (1) for the metal layer conductivity is set based on a case where the thickness of the metal layer 302 is in the range from 40 nm to 50 nm and an etching amount thereof is equal to or less than 30% (15 nm) of the thickness of the metal layer. Further, the condition (2) for the mask selectivity is set based on a case where the mask layer remains in a thickness of 300 nm or more. Since the metal layer 302 is made of the tungsten, a tungsten selectivity (W sel) is calculated as the metal layer selectivity. Further, since the mask layer is implemented by the ACL 304, an ACL selectivity (ACL sel) is calculated as the mask selectivity.

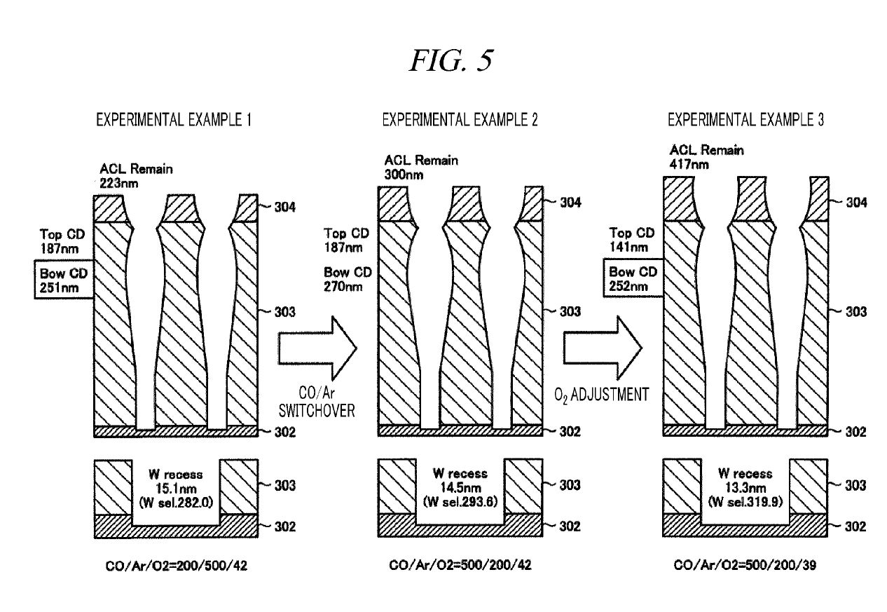

A variation in the etching as a result of adding the CO gas to the processing gas will be explained by using experimental examples. FIG. 5 is a diagram schematically illustrating hole shapes. Experimental examples 1 to 3 shown in FIG. 5 schematically illustrate SEM images of cross sections of the holes when 100% of over-etching is performed on the multilayered film 300 by setting the flow rates of the C₄F₆ gas and the N₂ gas contained in the processing gas to be as specified in the following as common conditions while varying flow rates of the CO gas, the Ar gas and the O₂ gas as follows.

### Common conditions

C₄F₆ gas: 54 sccm

N₂ gas: 100 sccm

### Experimental example 1

CO gas: 200 sccm

Ar gas: 500 sccm

O₂ gas: 42 sccm

### Experimental example 2

CO gas: 500 sccm

Ar gas: 200 sccm

O₂ gas: 42 sccm

### Experimental example 3

CO gas: 500 sccm

Ar gas: 200 sccm

O₂ gas: 39 sccm

In each of the experimental examples 1 to 3 shown in FIG. 5, a width (Top CD) near an opening of the hole, a maximum width (Bow CD) of the hole, a residual amount (ACL Remain) of the ACL 304 and an etching amount (W recess) of the metal layer 302 of tungsten are shown. Further, under the etching amount (W recess) of the metal layer 302 of tungsten, there is depicted the tungsten selectivity (W sel). By way of example, in the experimental example 1, the width (Top CD) near the opening of the hole is 187 nm; the maximum width (Bow CD) of the hole, 251 nm; the residual amount of the ACL 304, 233 nm; the etching amount of the metal layer 302 of tungsten, 15.1 nm; and the tungsten selectivity, 282.0.

In the experimental example 2, the flow rates of the CO gas and the Ar gas contained in the processing gas are switched from those of the experimental example 1. In case of switching the flow rates of the CO gas and the Ar gas, the maximum width (Bow CD) of the hole is increased by being affected by O of the CO gas. In the experimental example 3, a flow rate of the O₂ gas is adjusted such that the maximum width (Bow CD) of the hole becomes equal to that of the experimental example 1. In the experimental example 3, the maximum width (Bow CD) of the hole is 252 nm, which is close to 251 nm of the experimental example 1.

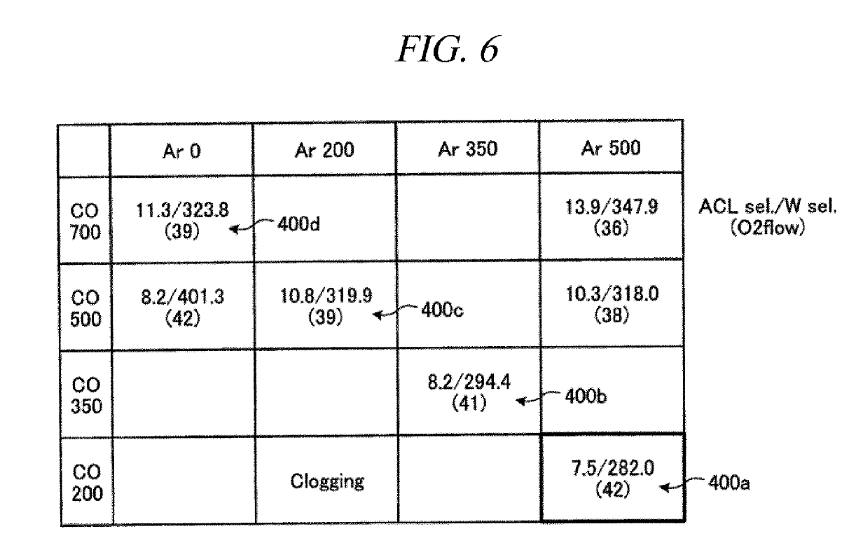

FIG. 6 is a table showing an example of measurement results of the ACL selectivity and the tungsten selectivity. FIG. 6 shows the measurement results of the ACL selectivity (ACL sel) and the tungsten selectivity (W sel) when the etching is performed by varying the flow rates of the CO gas and the Ar gas. Further, the flow rates of the C₄F₆ gas and the N₂ gas contained in the processing gas are set to be as the aforementioned common conditions. Further, the flow rate of the O₂ gas is adjusted such that the maximum width (Bow CD) of the hole is substantially same. Furthermore, for the multilayered film 300 etched by using the respective processing gases, it is checked whether a clogged hole exists. If there exists a clogged hole, it is marked “Clogging”.

In the table of FIG. 6, the leftmost column sections indicate cases where the flow rate of the CO gas is set to be 700 sccm, 500 sccm, 350 sccm and 200 sccm, and the topmost row sections indicate cases where the flow rate of the Ar gas is set to be 0 sccm, 200 sccm, 350 sccm and 500 sccm. In the table of FIG. 6, in each region where the column section and the row section intersect with each other, the ACL selectivity and the tungsten selectivity when the etching is performed with the CO gas at the flow rate specified in the column section and with the Ar gas at the flow rate specified in the row section are indicated as “ACL sel/W sel”. Further, in the table of FIG. 6, in each region where the column section and the row section intersect with each other, a value of the flow rate of the O₂ gas when the etching is performed is indicated as “O₂ Flow.”

By way of example, a region 400a in the table of FIG. 6 is directed to a case where the etching of the experimental example 1 of FIG. 5 is performed, and it is shown that: the ACL selectivity (ACL sel) is 7.5; the tungsten selectivity (W sel) is 282.0; and the flow rate of the O₂ gas in case of performing the etching is 42 sccm. Further, a region 400c in the table of FIG. 6 is directed to a case where the etching of the experimental example 3 of FIG. 5 is performed, and it is shown that: the ACL selectivity is 10.8, the tungsten selectivity is 319.9, and the flow rate of the O₂ gas in case of performing the etching is 39 sccm. In addition, in the regions 400a to 400d, the total flow rate of the CO gas and the Ar gas is set to be 700 sccm.

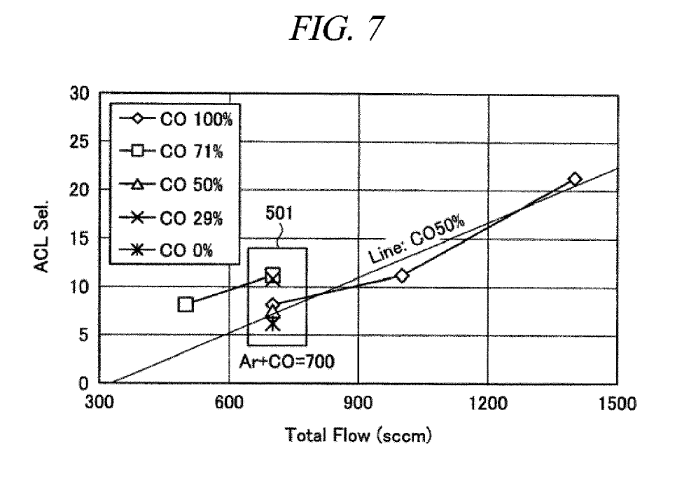

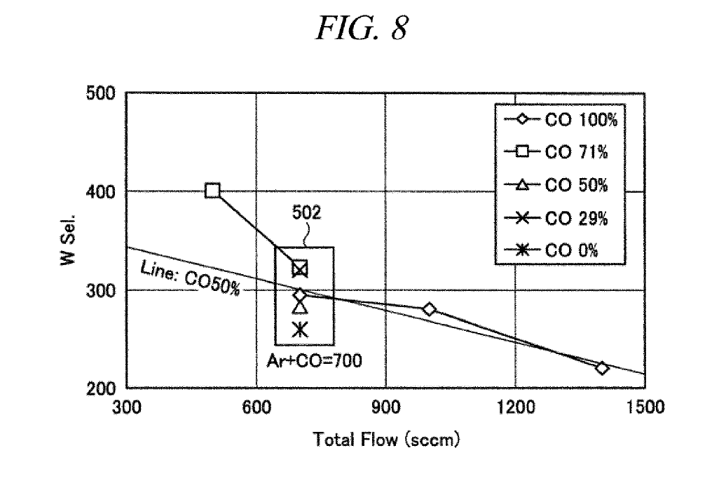

FIG. 7 is a diagram showing an example of a variation of the ACL selectivity. FIG. 8 is a diagram showing an example of a variation of the tungsten selectivity. FIG. 7 and FIG. 8 show measurement results of the ACL selectivity (ACL sel) and the tungsten selectivity (W sel) when a ratio of the flow rate of the CO gas to the total flow rate of the CO gas and the Ar gas is set to be 0%, 29%, 50%, 71% and 100%, respectively. Individual points included in a range 501 of FIG. 7 and a range 502 of FIG. 8 indicate individual values of the region 400a to 400d where the total flow rate of the CO gas and the Ar gas is set to be 700 sccm in the table of FIG. 6. Further, in FIG. 7 and FIG. 8, the measurement results of the ACL selectivity and tungsten selectivity when the total flow rate of the CO gas and the Ar gas is changed are also provided for the cases where the ratio is 50% and 100%.

A state in which the ratio of the flow rate of the CO gas to the total flow rate of the CO gas and the Ar gas is 0% is a case where the processing gas does not contain the CO gas, and states in which the ratios of the flow rate of the CO gas to the total flow rate of the CO gas and the Ar gas are 29%, 50%, 71% and 100%, respectively, are cases where the processing gas contains the CO gas. As shown in FIG. 7 and FIG. 8, the tungsten selectivity and the mask selectivity are found to be improved in the cases where the ratios are 29%, 50%, 70% and 100%, as compared to the case where the ratio is 0%. That is, it is found out that the tungsten selectivity and the mask selectivity are improved as an effect of adding the CO gas to the processing gas.

Further, as depicted in FIG. 7, the ACL selectivity tends to increase as the ratio of the flow rate of the CO gas to the total flow rate of the CO gas and the Ar gas is higher and, also, as the total flow rate of the CO gas and the Ar gas is higher. Meanwhile, as shown in FIG. 8, although the tungsten selectivity tends to increase as the ratio of the flow rate of the CO gas to the total flow rate of the CO gas and the Ar gas increases, the tungsten selectivity tends to decrease with a rise of the total flow rate of the CO gas and the Ar gas.

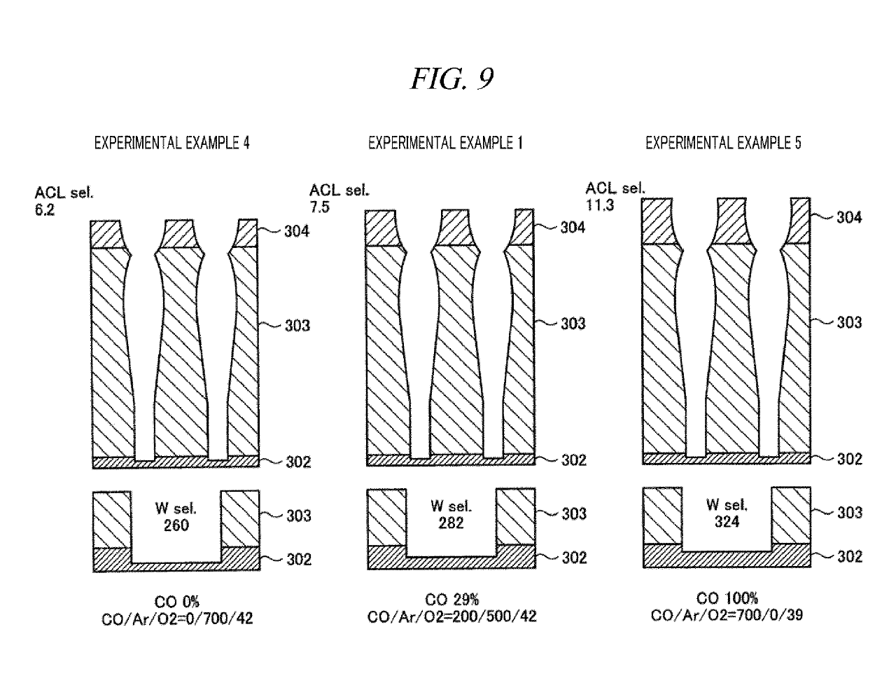

Now, an example of a variation of the etching depending on the variation of the ratio of the flow rate of the CO gas to the total flow rate of the CO gas and the Ar gas while the total flow rate of the CO gas and the Ar gas is maintained constant is explained. Here, the description will be provided for a case where the total flow rate of the CO gas and the Ar gas is set to be 700 sccm. FIG. 9 is a diagram schematically illustrating hole shapes. FIG. 9 shows a hole shape of the above-stated experimental example 1. Further, FIG. 9 also shows holes shapes of experimental examples 4 and 5. The experimental examples 4 and 5 shown in FIG. 9 schematically illustrate SEM images of cross sections of hole portions when 100% of the over-etching is performed on the multilayered film 300 by setting the flow rates of the C₄F₆ gas and the N₂ gas contained in the processing gas as the aforementioned common conditions while altering the flow rates of the CO gas, the Ar gas and the O₂ gas as follows.

### Experimental example 4

CO gas: 0 sccm

Ar gas: 700 sccm

O₂ gas: 42 sccm

### Experimental example 5

CO gas: 700 sccm

Ar gas: 0 sccm

O₂ gas: 39 sccm

Each of the experimental examples 1, 4 and 5 depicted in FIG. 9 shows the ACL selectivity (ACL sel) and the tungsten selectivity (W sel). The region 400a in the table of FIG. 6 corresponds to the experimental example 1.The region 400d in the table of FIG. 6 corresponds to experimental example 5.

The experimental example 4 indicates a case where the processing gas does not contain the CO gas. The experimental examples 1 and 5 indicate cases where the processing gas contains the CO gas. In the experimental examples 1 and 5, the tungsten selectivity and the mask selectivity are found to be improved as compared to the experimental example 4. That is, in FIG. 9 as well, it is found out that the tungsten selectivity and the mask selectivity are improved as a result of adding the CO gas to the processing gas.

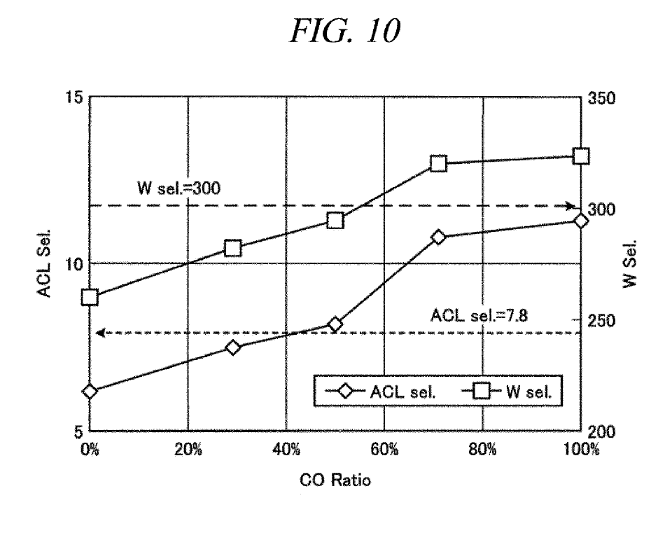

Now, ranges which satisfy the conditions (1) and (2) exhibiting the high metal selectivity and the mask selectivity in the present exemplary embodiment will be discussed. FIG. 10 is a diagram showing an example of variations of the tungsten selectivity and the ACL selectivity. Specifically, FIG. 10 shows the variations of the tungsten selectivity (W sel) and the ACL selectivity (ACL sel) depending on the ratio of the flow rate of the CO gas to the total flow rate of the CO gas and the Ar gas when the total flow rate is 700 sccm.

In FIG. 10, the tungsten selectivity and the ACL selectivity as the measurement results after the etching are plotted as quadrangular dots, and graphs of the tungsten selectivity and the ACL selectivity are indicated by connecting these quadrangular dots. Further, in FIG. 10, the tungsten selectivity under the condition (1) and the mask selectivity under the condition (2) are as indicated by discrete dashed lines.

From the graphs shown in FIG. 10, it is found out that the conditions (1) and (2) can be satisfied when the ratio of the flow rate of the CO gas to the total flow rate of the CO gas and the Ar gas is equal to or higher than 55%. That is, by setting the flow rate of the CO gas to be equal to or higher than 55% of the total flow rate of the CO gas and the Ar gas, the plasma processing apparatus 10 is capable of implementing the plasma etching in which both the tungsten selectivity of the condition (1) and the mask selectivity of the condition (2) are achieved.

Furthermore, in FIG. 10, according to the etching results indicated by the quadrangular dots, if the flow rate of the CO gas is equal to or higher than 71% of the total flow rate of the CO gas and the Ar gas, the conditions (1) and (2) are satisfied. That is, by setting the flow rate of the CO gas to be equal to or higher than 71% of the total flow rate of the CO gas and the Ar gas, the plasma processing apparatus 10 is capable of implementing the plasma etching in which both the tungsten selectivity of the condition (1) and the mask selectivity of the condition (2) are achieved.

Regarding the range of the flow rate of the CO gas with respect to the total flow rate of the processing gas, by setting the flow rate of the CO gas to be equal to or higher than 55% of the total flow rate of the processing gas, both the tungsten selectivity of the condition (1) and the mask selectivity of the condition (2) can be achieved. That is, by setting the flow rate of the CO gas to be equal to or higher than 55% of the total flow rate of the processing gas, the plasma processing apparatus 10 is capable of implementing the plasma etching in which both the tungsten selectivity of the condition (1) and the mask selectivity of the condition (2) are achieved.

In addition, if CO is considered in terms of a scavenger of F, the flow rate of the CO gas can be expressed as a ratio with respect to the flow rate of the C₄F₆ gas. By way of example, if the flow rate of the C₄F₆ is set to 1, the following Expression (3) is obtained.

9.3≤CO/C₄F₆≤13.0 (3)

That is, by setting the flow rate of the CO gas to be in the range from 9.3 times to 13 times the flow rate of the C₄F₆ gas, the plasma processing apparatus 10 is capable of implementing plasma etching in which both the tungsten selectivity of the condition (1) and the mask selectivity of the condition (2) are achieved.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A plasma processing method, comprising:
supplying a processing gas containing at least a fluorocarbon-based gas or a hydrofluorocarbon-based gas and CO into a processing vessel in which a multilayered film having at least an oxide layer, a conductive layer provided under the oxide layer and a mask layer provided on a top surface of the oxide layer is disposed; and
etching the multilayered film by generating plasma within the processing vessel into which the processing gas is supplied.

2. The plasma processing method of claim 1,
wherein the conductive layer is implemented by a metal layer or a silicon-containing layer, and
the processing gas contains a C₄F₆ gas as the fluorocarbon-based gas.

3. The plasma processing method of claim 1,
wherein the processing gas further contains a rare gas, and
a flow rate of the CO is set to be equal to or higher than 55% of a total flow rate of the rare gas and the CO.

4. The plasma processing method of claim 3,
wherein the flow rate of the CO is set to be equal to or higher than 71% of the total flow rate of the rare gas and the CO.

5. The plasma processing method of claim 1,
wherein a flow rate of the CO is set to be equal or higher than 55% of a total flow rate of the processing gas.

6. The plasma processing method of claim 2,
wherein a flow rate of the CO is set to be in a range from 9.3 times to 13 times a flow rate of the C₄F₆ gas.

7. A plasma processing apparatus, comprising:
a processing vessel configured to accommodate therein a multilayered film having at least an oxide layer, a metal layer provided under the oxide layer and a mask layer provided on a top surface of the oxide layer;
a supply unit configured to supply a processing gas containing at least a fluorocarbon-based gas or a hydrofluorocarbon-based gas and CO into the processing vessel; and
a plasma generation unit configured to etch the multilayered film by generating plasma within the processing vessel into which the processing gas is supplied.
